(19) United States
(12) Patent Application Publication
(10) Pub. No.: US 2026/0039167 A1
(43) Pub. Date: Feb. 5, 2026

(54) ELECTROMOTIVE RADIATOR FAN OF A MOTOR VEHICLE AND MOTOR SUPPORT PLATE ASSEMBLY FOR THE RADIATOR FAN

(71) Applicant: Brose Fahrzeugteile SE & Co. Kommanditgesellschaft, Würzburg, Würzburg (DE)

(72) Inventors: Maik RÜMMLER, Breitengüssbach (DE); Luca STEGERS, Bamberg (DE); Vijaykumar JADHAV, Bamberg (DE)

(21) Appl. No.: 19/289,293

(22) Filed: Aug. 4, 2025

(30) Foreign Application Priority Data
Aug. 2, 2024 (DE) 10 2024 207 370.9

(51) Int. Cl. H02K 5/18; F04D 25/06; F04D 29/64; H02K 11/33; H02K 21/22

(52) U.S. Cl. CPC H02K 5/18; F04D 25/06; F04D 29/646; H02K 11/33; H02K 21/22

(57) ABSTRACT

An electromotive radiator fan for a motor vehicle contains a fan shroud with a motor mount by which a fan axis is defined, a motor support plate which is arranged on the front face of the motor mount, an electric motor which is inserted into the motor mount and held there by the motor support plate, and an electronic motor control unit which is arranged on the motor support plate. The electronic motor control unit is arranged with its center of area eccentric to the fan axis and/or not intersecting the fan axis. A corresponding motor support plate electronic motor control unit is also provided for such a radiator fan.

### CROSS-REFERENCE TO RELATED APPLICATION

This application claims the priority, under 35 U.S.C. § 119, of German Patent Application DE 10 2024 207 370.9, filed Aug. 2, 2024; the prior application is herewith incorporated by reference in its entirety.

### FIELD AND BACKGROUND OF THE INVENTION

The invention relates to an electromotive radiator fan of a motor vehicle with a fan shroud having a motor mount, a motor support plate, an electric motor, and an electronic motor control unit. The invention further relates to a motor support plate with an electronic motor control unit for such a radiator fan.

Motor vehicles with an internal combustion engine generate considerable heat during operation. To maintain the operating temperature, particularly within an engine cooling system, a coolant is typically used which, in turn, must be cooled. This usually happens when cooling air passes over cooling fins that are in thermal equilibrium with the coolant. Since the airflow is normally not adequate for cooling, particularly at low driving speeds, it is possible, for example, to attach a cooling fan with a radiator shroud and an electric (electromotive) drive to the radiator surrounding the cooling fins which generates an additional air flow that is guided by the shroud body. The (fan) drive has an electric motor for this purpose which is coupled to a drive part, in particular to a fan wheel which generates the air flow.

Conventionally, the shroud body has a substantially round recess within which the fan drive is arranged. The plane in which the fan wheel is located is substantially parallel to the plane of the cooling fins. The motor, which is coupled to the fan wheel for drive purposes, is usually fixed to a rigid motor mount at the front by means of screws or rivets, the (motor) mount being held in the center of the recess by means of radially extending struts.

For example, brushless electric motors are used in which a rotor mounted on a stator is driven by a rotating magnetic field. In that case, phase windings of the rotor (rotating-field winding) are supplied with a corresponding electrical three-phase or motor current which is controlled and regulated by an electronic motor control unit (i.e., a controller or motor electronics).

The motor control unit is usually arranged on a substantially flat cover element which, in turn, is arranged on the motor support plate and can, in particular, be manufactured integrally therewith. This cover element—optionally in conjunction with another, rear cover of the electronic motor control unit for the purpose of encapsulating it—protects the electronic components of the electronic motor control unit from environmental influences such as moisture and dust particles and also dissipates heat from the electronic components by thermally connecting them to the cover element (and, optionally, the rear cover) by means of a thermal paste.

However, the cover element obstructs or impedes the air flow for convective cooling of the coil windings of the electric motor, which can cause the coil windings to heat up slightly when the cooling fan is in operation. The resulting heat is substantially transferred to the motor support plate, which also results in increased heat transfer to the electronic components of the electronic motor control unit. This, in turn, can adversely affect the operation of the electronic motor control unit, which is why the electronic components must be configured to withstand higher temperatures, possibly resulting in additional production costs.

### SUMMARY OF THE INVENTION

It is therefore the object of the invention to provide an electromotive radiator fan of a motor vehicle with improved discharging of waste heat. It is also an object of the invention to provide a motor support plate for such a radiator fan.

According to the invention, the object is achieved with regard to the radiator fan by the features of the independent radiator fan claim and with regard to the motor support plate by the features of the independent motor support plate claim. Advantageous embodiments and refinements constitute the subject matter of the subclaims and of the description that follows. The radiator fan according to the invention shares the advantages of the motor support plate according to the invention. The advantages and designs mentioned with regard to the radiator fan are also applicable to the motor support plate.

With the foregoing and other objects in view there is provided, in accordance with the invention, an electromotive radiator fan for a motor vehicle. The radiator fan includes a fan shroud having a motor mount by which a fan axis is defined, a motor support plate disposed on a front face of the motor mount, an electric motor inserted into the motor mount and held on the motor mount by the motor support plate, and an electronic motor controller disposed on the motor support plate. The electronic motor controller is disposed with its center of area eccentric to the fan axis and/or does not intersect the fan axis.

The electromotive or electric radiator fan according to the invention is suitable and designed for a motor vehicle. The radiator fan has a fan shroud with a motor mount (motor support) or with a motor bracket. The fan shroud has, for example, a circular recess in which the ring-shaped motor mount is held by a number of approximately radially extending struts. The motor mount is advantageously a plastic part, in particular an injection-molded part with a comparatively low thermal conductivity. The fan shroud and/or the motor mount define a fan axis, which is in particular constituted by a rotation axis of a rotor of the radiator fan that is arranged in the fan shroud, which rotor is preferably designed for rotation around the motor mount.

An electric motor is inserted into the motor mount and is held in place by a motor support plate that is arranged on the front face of the motor mount. The motor support plate thus supports the electric motor, and furthermore the motor support plate also supports an electronic motor control unit, which preferably controls and/or regulates the three-phase electrical or motor current for the operation of the electric motor. The motor mounting plate is preferably manufactured as a metallic component, for example as a die-cast part. Preferably, the rotation axis of the electric motor coincides with the fan axis.

To support the electronic motor control unit, a cover element is attached to the motor support plate, in particular formed integrally therewith, which cover element supports the electronic motor control unit and to which the latter is fastened. The cover element is preferably arranged on or adjacent to the side of the motor support plate situated opposite or facing away from the electric motor or is (at least partially) incorporated therein (in the case of integral manufacturing).

The electronic motor control unit is now arranged on the motor support plate with its center of area eccentric to the fan axis and/or in such a way that it does not intersect the fan axis.

The conjunction “and/or” is to be understood here and in the following such that the features linked by this conjunction can be formed both jointly and as alternatives to one another.

The center of area of the electronic motor control unit is constituted in particular by the center of area of a circuit board on which all of the electronic components of the electronic motor control unit are arranged and contacted, or preferably by the center of area of the abovementioned cover element on which the electronic motor control unit is arranged on the motor support plate.

The center of area can preferably be defined as

$$\vec{s} = \frac{1}{A} {\int }_{A} \vec{x} dA$$

i.e., via the surface integral of a vector in the plane of the circuit board or the cover element over the total area A of the circuit board or cover element.

An eccentric arrangement of the center of area with respect to the fan axis means, in particular, that the center of area, preferably as defined above, does not coincide with the fan axis. Preferably, the center of area is at a distance from the fan axis corresponding to at least 10%, especially preferably at least 20% of the largest longitudinal side of the electronic motor control unit.

In addition or alternatively, the electronic motor control unit is arranged on the motor support plate in such a way that it does not intersect the fan axis. In particular, the circuit board and, if applicable, the cover element carrying the electronic motor control unit are not intersected by the fan axis.

The two notions of not centering the electronic motor control unit on the fan axis and/or having it not intersect at all contribute to improved ventilation of the electric motor and thus to better heat dissipation.

In the central region of the cooling fan (i.e., near the fan axis), in which the wind speed decreases with decreasing distance from the fan axis (comparable to the center of a tornado), an air flow is created for convective cooling of the electronic motor control unit and the coil windings of the electric motor, primarily due to the difference in air pressure that develops on both sides of the cooling fan as a result of the rotation of the rotor and the air masses moved as a result.

By virtue of the proposed arrangement of the electronic control unit, the central region of the motor support plate in particular can now be cooled more easily by the air flow, since it is no longer or no longer substantially covered by the electronic motor control unit, for which reason the air flow is significantly less affected by it there.

Through appropriate cooling openings in the motor support plate, particularly in the central region, the air flow generated by the air pressure differences developing on both sides can also flow into the motor mount and particularly into the inner region of the electric motor, where it can provide cooling for the coil windings of the electric motor. The design and arrangement of the electronic control unit according to the invention also, in particular, enables complete coverage of the coil windings in the critical region around the axis to be avoided.

The improved cooling of the coil windings also reduces the heat input to the motor mounting plate and thus to the electronic motor control unit. This enables the performance of the electric motor in terms of power, torque, and speed to be improved for a given motor geometry (i.e., dimensions and number of turns) and also enables the nominal temperature for which the electronic components of the electronic motor control unit (such as electrolytic capacitors and/or chokes) must be configured to be lowered, which contributes to cost savings in the manufacturing process.

Preferably, the flat cover element is embedded in the motor support plate on which the electronic motor control unit is arranged. This includes, in particular, the case in which the cover element is manufactured integrally with the motor support plate. The motor support plate can, in particular, be shaped in such a way that, in the vicinity of the cover element, it is substantially constituted by the cover element and thus has, in particular, no other larger, structure-forming elements (any bulges in the cover element for accommodating electronic components are not to be regarded as “structure-forming”) in the vicinity of the cover element in the axial direction (defined with respect to the fan axis) apart from individual cooling nubs or the like. In particular, the cover element can be embedded in the structure which forms the motor support plate in the region outside the first cover element.

In an advantageous embodiment, the electronic motor control unit has an L-shape or a ring shape or a triangular shape or a rectangular shape or a pentagonal shape or a circular shape or a D-shape or a trapezoidal shape. In particular, a cover element of the type described above also has the corresponding shape. In particular, an L-shape or a ring shape allow for easy arrangement of the electronic motor control unit in such a way that the fan axis is not intersected. A triangular shape, a rectangular shape, a pentagonal shape, a D-shape, or a trapezoidal shape enable the center of area to be easily shifted away from the fan axis while still allowing contact to the coil windings (even at their “inner” end) from the electronic motor control unit.

It also proves advantageous if the motor support plate has a first plurality of cooling openings and/or a second plurality of cooling fins. The cooling fins enable the motor mounting plate to more easily dissipate the waste heat transferred from the electric motor to the afore-described air flow, since the surface area of the motor mounting plate through which the heat is dissipated is increased. The cooling openings enable the air flow to penetrate into the motor mount, where it provides better cooling of the coil windings.

Preferably, the motor support plate has a lattice structure, in particular a radial one, that is formed by the cooling fins and the cooling openings formed between two respective cooling fins. This includes, in particular, a case in which the motor support plate, in the region in which it has cooling fins and openings, has the lattice structure, preferably formed by radial cooling fins and any arched cross struts (which may also be provided by cooling fins). The cooling openings are thus formed between the cooling fins, and the resulting lattice structure forms the motor support plate in the relevant region, which in particular does not form any further flat plate structure in the relevant region that would cover the space created between the cooling fins.

Preferably, the lattice structure extends at least over the region of the motor support plate which is not covered by the electronic motor control unit. This includes, in particular, a case in which the motor support plate is formed substantially (i.e., in particular with the exception of mounting tabs or flanges, etc.) by the flat cover element for the electronic motor control unit and by the cooling fins and their connecting struts, which form the lattice structure. This enables the largest possible surface area of the motor support plate to be provided for cooling the coil windings of the electric motor.

In another advantageous embodiment, the cooling openings have a rectangular shape and/or a triangular shape and/or a circular shape and/or a circular sector shape and/or a D-shape. A rectangular shape or a circular shape is especially easy to achieve in terms of manufacturing (particularly if the cooling openings are not contained in the die-cast part but are created by subsequent drilling or cuts, etc.). A triangular shape or a circular sector shape enables the cooling openings to form a radial pattern and thus, in particular, the abovementioned radial lattice structure.

It is also advantageous if a width and/or an axial depth of the cooling fins has a variation of at least 50% relative to the narrowest or flattest cooling fin. This means in particular that the cooling fins can have a different width (in the plane perpendicular to the fan axis, particularly in the tangential direction) and/or a different axial depth (i.e., in the direction of the fan axis), and the variation in the width or depth can be at least 50%, preferably at least 80%, of the respective minimum value. For example, if the narrowest cooling fin has a width of 3 mm, the widest cooling fin is at least 4.5 mm or, respectively, at least 5.4 mm wide.

Advantageously, the motor support plate protrudes radially over the motor mount with respect to the fan axis. In particular, the motor support plate protrudes beyond the motor mount in all radial directions. This enables the surface area for cooling by the air flow to be further increased.

The motor support plate according to the invention with an electronic motor control unit is suitable and configured for a radiator fan as described above.

Other features which are considered as characteristic for the invention are set forth in the appended claims.

Although the invention is illustrated and described herein as embodied in an electromotive radiator fan of a motor vehicle, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 is a diagrammatic, perspective view of a radiator fan with a fan shroud;

FIG. 2 is an exploded, perspective view of a motor support plate with an electric motor for the radiator fan according to FIG. 1;

FIG. 3 is a top plan view of the motor support plate with an electronic motor control unit for the electric motor according to FIG. 2; and

FIG. 4 is a top plan view of an embodiment of the motor support plate with the electronic motor control unit as an alternative to the embodiment of FIG. 3.

Analogous parts and quantities are provided with the same respective reference symbols in all figures. Only some among a number of identical parts are provided with the corresponding reference symbols.

### DETAILED DESCRIPTION OF THE INVENTION

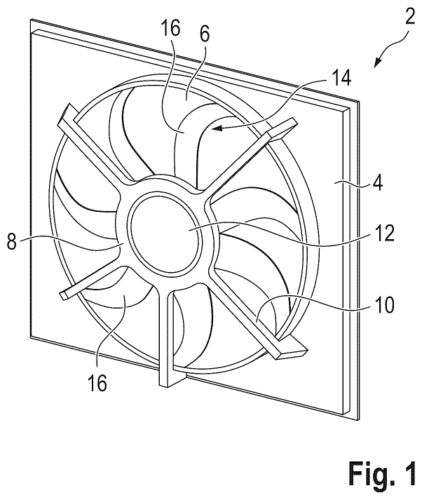

Referring now to the figures of the drawings in detail and first, particularly to FIG. 1 thereof, there is shown a schematic oblique view of an electromotive radiator fan 2 of a motor vehicle (not shown in detail). The radiator fan 2 has a fan shroud 4 with a circular recess 6 in which a ring-shaped motor mount 8 with a number of radially extending struts 10 is held.

An electric motor 12 is arranged inside the motor mount 8 and held there by a motor support plate which is not shown in FIG. 1 and will be described later. The electric motor 12 is drive-coupled to a fan wheel 14 which has a plurality of (in the present embodiment: seven) rotor blades 16. The drive coupling of the electric motor 12 with the fan wheel can in particular consist of a rigid connection of the fan wheel to a rotor of the electric motor 12 (not shown in detail in FIG. 1), which rotor is caused to rotate during operation of the radiator fan 2 against a stator of the electric motor 12 (not shown) which is rigidly connected to the fan shroud 4 via the struts 10, the motor mount 8, and the motor support plate.

The fan shroud 4—defined in particular by the rotational symmetry of the recess 6 and motor mount 8—defines a fan axis A (not shown in FIG. 1) which simultaneously forms the axis of rotation of the electric motor 12 and thus also of the fan wheel 12.

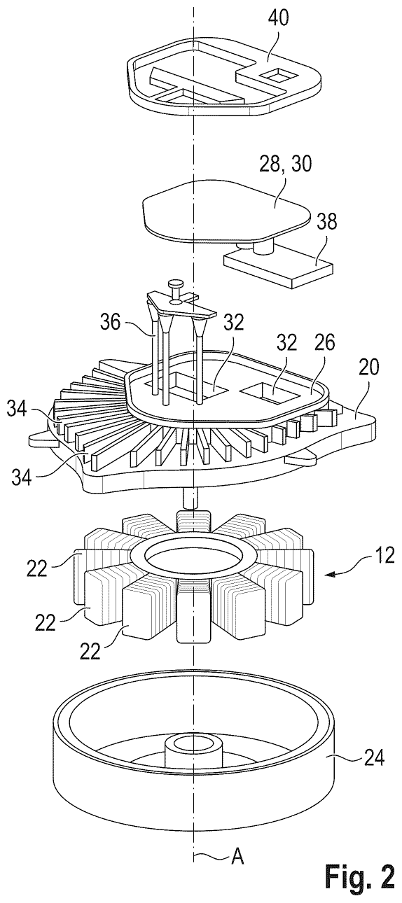

FIG. 2 shows an exploded view of the electric motor 12 according to FIG. 1 together with a motor support plate 20 holding it in the motor mount 8. The electric motor 12 has a plurality of coils 22 that are arranged radially with respect to the fan axis A (shown in dashed lines in FIG. 2) with respective corresponding coil windings. The electric motor 12 further contains a rotor 24 which, during operation of the electric motor 12, is caused to rotate about the fan axis A against the coils 22.

A flat cover element 26 is embedded in the motor support plate 20 which is formed integrally with the motor support plate 20, for example as an in particular metallic die-cast part. The cover element 26 serves to accommodate an electronic motor control unit 28, which is designed to control and/or regulate the electric three-phase or motor current of the electric motor 12 during operation. The electronic motor control unit 28 is shown here only from the rear side, which is constituted by the underside of a circuit board 30 (e.g., a PCB), on which all electronic components (not shown) of the electronic motor control unit 28 are arranged and contacted.

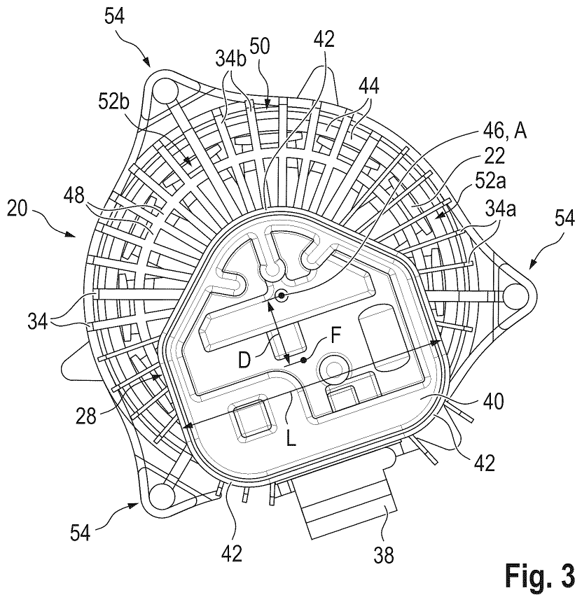

In addition, pocket-like recesses 32 are provided in the cover element 26 of the motor support plate 20 for receiving the electronic components of the electronic motor control unit 28 which project spatially beyond a circuit board 30. The motor support plate 20 also has a plurality of cooling fins 34, which will be described in greater detail later. Phase connections 36 which are fed through the motor support plate 20 and electrically connected to the coils 22 in order to be supplied with three-phase or motor current are electrically connected to the electronic motor control unit 28 and arranged thereon (i.e., on the circuit board 30). The electronic motor control unit 28 also has a power connection 38 for connection to a wiring harness or the like of the motor vehicle via which the power supply to the electronic motor control unit 28 and thus to the radiator fan 2 is provided. The rear side of the electronic motor control unit 28 visible in FIG. 2 is covered by a flat rear cover 40 which substantially replicates the shape of the circuit board 30 and/or cover element 26. The specific arrangement of the electronic motor control unit 28 on the motor support plate 20 is described in FIG. 3 (see below).

The circuit board 30 of the electronic motor control unit 28 can be fastened to the motor support plate 20 by means of one or more screws and can also be held by through adhesion of the electronic components in the recesses 32 by means of an (at least partially) adhesive thermal paste (not shown in each case). The rear cover 40 can be held by frictional engagement with the motor support plate 20 in the vicinity of the cover element 26 and, moreover, can also be adhered to the rear side of the circuit board 30 by means of a thermal paste.

FIG. 3 shows a plan view of the motor support plate 20 according to FIG. 2 with the electronic motor control unit 28, which is covered by the rear cover 40 in the present view. The rear cover 40 has substantially the same shape as the cover element 26 according to FIG. 2 and, apart from generously rounded corners 42, follows the shape of the electronic motor control unit 28 which, in turn, is determined by the shape of the circuit board 30 (see FIG. 2).

The motor support plate 20 has a plurality of cooling fins 36 between which cooling openings 44 are formed. The cooling fins 36 are each arranged radially with respect to a center point 46 and are connected to one another by arched cross struts 48, so that a lattice structure 50 is formed in the region of the motor support plate 20 which is not covered by the electronic motor control unit 28 (or by the cover element 26 according to FIG. 2).

The cooling fins 36 can, in particular, have different widths. For instance, it can be seen in FIG. 3 that the cooling fins 34a in a first region 52a of the motor support plate 20, which lies laterally or tangentially next to the electronic motor control unit 28, have a smaller width than the cooling fins 34b in a second region 52b of the motor support plate 20, which lies frontally or radially in front of the electronic motor control unit 28. There, the cooling fins 34b expand to a width which is preferably at least 50% greater than Ba. The cooling openings 44 preferably have a shape that narrows toward the center point 46, that is, a trapezoidal shape or the shape of a circular sector or of a circular sector arc. However, in another embodiment of the motor support plate 20 that is not shown, the cooling openings 44 may also have other suitable shapes.

The center point 46 of the lattice structure 50 coincides with the fan axis A. The motor support plate 20 projects in the radial direction (with respect to the center point 46 or the fan axis A) completely over the electric motor 12, which is arranged below the image plane in the illustration according to FIG. 3 and whose coils 22 can be seen through the cooling openings 44. The motor support plate 20 also has three fastening tabs 54 for fastening to the fan shroud 4 which are each offset from one another by 120° (with respect to the center point 46 or with respect to the fan axis A), whereby the motor support plate 20 takes on an approximate shape of an equilateral triangle with a superposed circle.

In order to achieve better ventilation and thus also cooling, especially of the interior of the coils 22, which generate more heat per unit volume in the interior due to the closer arrangement, the electronic motor control unit 28 is not arranged centrally on the motor support plate 20 but is offset relative to the center point 46 of the lattice structure 50 of the motor support plate 20 and thus also relative to the fan axis A. This means in particular that the center of area F of the electronic motor control unit 28 (which, in the present case, is assumed to be approximately equal to the corresponding center of area of the cover element 26 or to the center of area of the rear cover 40) is shifted non-trivially (i.e., particularly in a noticeable manner) relative to the fan axis A.

The center of area F of the electronic motor control unit 28 (which, in the present case, is also assumed to be the center of area of the cover element not shown in FIG. 3 and of the rear cover 40, see above) has a distance D from the fan axis A which corresponds to greater than 20% of the largest longitudinal side L of the electronic motor control unit 28 (or its rear cover 40).

In the present exemplary embodiment, the electronic motor control unit 28 has a substantially pentagonal shape (or the rough shape of a house facade with a gable) except for the rounded corners 42. Other shapes are also conceivable, however. In particular, shapes for the electronic motor control unit 28 are also conceivable which do not intersect the fan axis A at all, for example an L-shape or a ring shape (around the fan axis A).

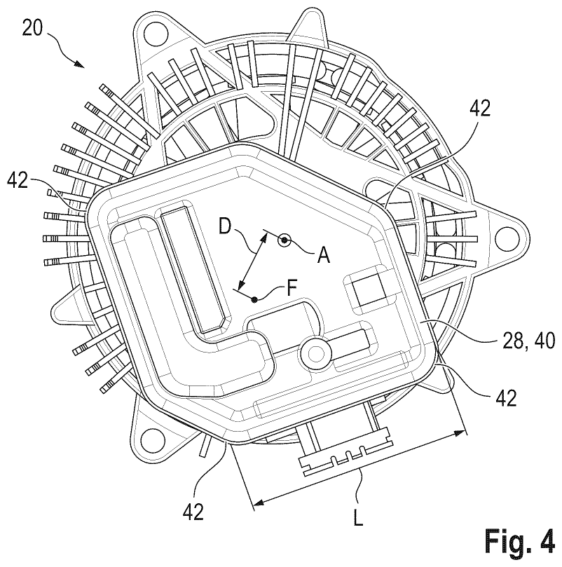

FIG. 4 shows a top view of an embodiment of the motor support plate 20 with an electronic motor control unit 28 as an alternative to the embodiment of FIG. 3. The electronic motor control unit 28 (or, here, the rear cover 40 visible in the plan view) has the shape of a square except for the rounded corners 42, which are flattened to varying degrees at two opposite corners. The less pronounced flattening 56 is located on the outside of the electronic motor control unit 28 (relative to the motor support plate 20), whereas the more pronounced flattening 58 (i.e., the correspondingly longer “diagonal” side) is arranged inside the motor support plate 20. For the electronic motor control unit 28 according to FIG. 4 (or for its rear cover 40 and the cover element, which is not shown), the center of area F is also noticeably shifted relative to the fan axis A, whereby here, too, the distance D of the center of area F to the fan axis A corresponds to greater than 20% of the largest longitudinal side L (calculated plus the rounded corners 42). The arrangement of the electronic motor control unit 28 according to FIG. 4 also enables the cooling fins 36 to achieve better cooling of the interior of the coils 22 than with a central arrangement (that is, if the center of area F were to lie directly on the fan axis, or the distance D were negligible compared to the dimensions).

In addition to the fastening tabs 54, the motor support plate 20 according to FIG. 4 has a strut structure 56 between them which mechanically supports the lattice structure 50 formed by the cooling fins 36.

Although the invention has been illustrated and described in detail on the basis of the preferred embodiment, the invention is not limited to the disclosed examples, and other variations may be derived therefrom by those skilled in the art without departing from the scope of the invention.

The following is a summary list of reference numerals and the corresponding structure used in the above description of the invention:
2 radiator fan
4 fan shroud
6 recess
8 motor mount
10 strut
12 electric motor
14 fan wheel
16 rotor blades
20 motor support plate
22 coils
24 rotor
26 cover element
28 electronic motor control unit
30 circuit board
32 bulge
34 cooling fins
34a/b cooling fins
36 phase connection
38 power connection
40 rear cover
42 rounded corners
44 cooling holes
46 center point
48 cross strut
50 lattice structure
52a/b first/second region
54 fastening tabs
56 strut structure
A fan axis
Ba/b first/second width
D distance
F center of area
L (largest) longitudinal side

1. An electromotive radiator fan for a motor vehicle, comprising:
a fan shroud having a motor mount by which a fan axis is defined;
a motor support plate disposed on a front face of said motor mount;
an electric motor inserted into said motor mount and held on said motor mount by said motor support plate; and
an electronic motor controller disposed on said motor support plate, said electronic motor controller disposed with its center of area eccentric to the fan axis and/or does not intersect the fan axis.

2. The radiator fan according to claim 1, further comprising a flat cover element embedded in said motor support plate and on which said electronic motor controller is disposed.

3. The radiator fan according to claim 1, wherein said electronic motor controller has an L-shape, or a ring shape, or a triangular shape, or a rectangular shape, or a pentagonal shape, or a circular shape, or a D-shape, or a trapezoidal shape.

4. The radiator fan according to claim 1, wherein said motor support plate has a plurality of cooling openings formed therein and/or a plurality of cooling fins.

5. The radiator fan according to claim 4, wherein said motor support plate has a lattice structure that is formed by said cooling fins and said cooling openings that are formed between two respective said cooling fins.

6. The radiator fan according to claim 5, wherein said lattice structure extends at least over a region of said motor support plate which is not covered by said electronic motor controller.

7. The radiator fan according to claim 4, wherein said cooling openings have a rectangular shape and/or a triangular shape and/or a circular shape and/or a circular sector shape and/or a D-shape.

8. The radiator fan according to claim 4, wherein a width and/or an axial depth of said cooling fins has a variation of at least 50% relative to a narrowest or flattest one of said cooling fins.

9. The radiator fan according to claim 1, wherein said motor support plate projects beyond said motor mount in a radial direction with respect to the fan axis.

10. A motor support plate assembly for a radiator fan, comprising:
a motor support plate; and
an electronic motor controller supported by said motor support plate.
